(19) United States
(12) Patent Application Publication
(10) Pub. No.: US 2024/0379650 A1
(43) Pub. Date: Nov. 14, 2024

(54) FILTER AND MANUFACTURING METHOD THEREFOR

(71) Applicants: Beijing BOE Optoelectronics Technology Co., Ltd., Beijing (CN); BOE TECHNOLOGY GROUP CO., LTD., Beijing (CN)

(72) Inventors: Qichang AN, Beijing (CN); Yuelei XIAO, Beijing (CN); Yue LI, Beijing (CN); Yingwei LIU, Beijing (CN); Yi ZHOU, Beijing (CN); Yifan WU, Beijing (CN); Yulin FENG, Beijing (CN); Kidong HAN, Beijing (CN); Xue CAO, Beijing (CN); Wenbo CHANG, Beijing (CN); Lihui WANG, Beijing (CN); Qiuxu WEI, Beijing (CN); Biqi LI, Beijing (CN)

(73) Assignees: Beijing BOE Optoelectronics Technology Co., Ltd., Beijing (CN); BOE TECHNOLOGY GROUP CO., LTD., Beijing (CN)

(21) Appl. No.: 18/690,704

(22) PCT Filed: Apr. 27, 2022
(86) PCT No.: PCT/CN2022/089631

§ 371 Date: Mar. 8, 2024

(51) Int. Cl. H01L 27/01; H01L 23/48; H01L 23/522; H01L 23/528; H01L 23/532; H03H 7/01; H03H 7/06

(52) U.S. Cl. CPC H01L 27/016; H01L 23/481; H01L 23/5223; H01L 23/5227; H01L 23/5228; H01L 23/528; H01L 23/5283; H01L 23/53238; H01L 23/53261; H01L 23/53266; H01L 28/10; H03H 7/0153; H03H 7/06

(57) ABSTRACT

A filter and a manufacturing method thereof are provided. The filler includes a first inductor, and further includes: a base substrate, having a plurality of through-holes passing therethrough; a plurality of conductive pillars, respectively corresponding to the through-holes, filled in the through-hole corresponding thereto, and forming a portion of a coil of the first inductor; a first conductive layer, provided on the base substrate, and comprising a plurality of first conductive wires, the first conductive wire being connected between two conductive pillars, and being configured to form a portion of the coil of the first inductor; and a second conductive layer, provided on a side, away from the base substrate, of the first conductive layer, and comprising second conductive wires, the second conductive wires corresponding to the first conductive wires respectively, and the second conductive wire being connected to the first conductive wire corresponding thereto through a via-hole.

### CROSS-REFERENCE TO RELATED APPLICATIONS

The present application is the U.S. National Stage of International Application No. PCT/CN2022/089631 filed on Apr. 27, 2022, the entire contents of which are incorporated herein by reference for all purposes.

### TECHNICAL FIELD

The present disclosure relates to the field of electronic technology, and specifically, to a filter and a manufacturing method thereof, and an electronic device.

### BACKGROUND

In the related art, the integrated passive device technology can reduce the area of a passive device by more than 80%. Based on different substrates, the integrated passive device technology may be divided into silicon-based, low-temperature co-fired ceramic-based, glass-based and other technologies.

The glass-based technology may bring a device a smaller size, and thus has become the mainstream technology for the integrated passive devices. However, a conductive wire formed on a glass substrate may be detached from the glass substrate since there is a large difference between the coefficient of thermal expansion of the conductive wire and that of the glass substrate.

It is to be understood that the above information disclosed in the Background section is only for enhancement of understanding of the background of the present disclosure and therefore it may contain information that does not form the prior art that is already known to a person skilled in the art.

### SUMMARY

An object of the present disclosure is to provide an array substrate and a display panel, and a display device.

An aspect of the present disclosure provides a filter including a first inductor. The filter further includes: a base substrate, having a plurality of through-holes passing through the base substrate; a plurality of conductive pillars, respectively corresponding to the through-holes, the conductive pillar being filled in the through-hole corresponding thereto, and the conductive pillars being configured to form a portion of the first inductor coil; a first conductive layer, provided on a side of the base substrate, the first conductive layer including a plurality of first conductive wires, the first conductive wire being connected between two of the conductive pillars, and the first conductive wires being configured to form a portion of the first inductor coil; and a second conductive layer, provided on a side, away from the base substrate, of the first conductive layer, the second conductive layer including second conductive wires, the second conductive wires corresponding to the first conductive wires respectively, and the second conductive wire being connected to the first conductive wire corresponding thereto through a via-hole.

In an embodiment of the present disclosure, a thickness of the first conductive layer is less than a thickness of the second conductive layer.

In an embodiment of the present disclosure, the thickness of the second conductive layer is 5 to 20 times the thickness of the first conductive layer.

In an embodiment of the present disclosure, an orthographic projection, on the base substrate, of the second conductive wire falls on an orthographic projection, on the base substrate, of the first conductive wire.

In an embodiment of the present disclosure, the second conductive wire is connected to the first conductive wire corresponding thereto through a plurality of via-holes, as for a plurality of via-holes and two conductive pillars connected to a same first conductive wire, an orthographic projection, on the base substrate, of one conductive pillar is at least partially overlapped with an orthographic projection, on the base substrate, of one o via-hole, and an orthographic projection, on the base substrate, of another conductive pillar is at least partially overlapped with an orthographic projection, on the base substrate, of another via-hole.

In an embodiment of the present disclosure, the first conductive layer and the conductive pillar are integrally moulded.

In an embodiment of the present disclosure, a gap is provided between at least a portion, facing the first conductive layer, of the conductive pillar and the first conductive layer.

In an embodiment of the present disclosure, the conductive pillar is a hollow conductive pillar, and an extension direction of a cavity in the conductive pillar is the same as an extension direction of the conductive pillar.

In an embodiment of the present disclosure, the filter further includes: a support pillar, filled within the cavity of the hollow conductive pillar, wherein the support pillar has a coefficient of thermal expansion between a coefficient of thermal expansion of the conductive pillar and a coefficient of thermal expansion of the base substrate.

In an embodiment of the present disclosure, the through-hole has a same aperture area at various locations; or the aperture area of the through-hole decreases gradually from one side of the base substrate to another side of the base substrate; or the aperture area of the through-hole decreases gradually from both sides of the base substrate to a middle position of the base substrate.

In an embodiment of the present disclosure, a minimum distance between adjacent through-holes is L1, the through-hole has a maximum inner diameter of R1, and L1 is greater than or equal to 2*R1.

In an embodiment of the present disclosure, the through-hole has an extension length of L2 and a minimum inner diameter of R2, and L2 is greater than or equal to 3*R2 and less than or equal to 7*R2.

In an embodiment of the present disclosure, the filter further includes a capacitor, and the capacitor has a first electrode connected to a first terminal of the first inductor, the first conductive layer further includes: a first conductive part, connected to the first conductive wire and being configured to form the first electrode of the capacitor. The filter further includes: a third conductive layer, provided between the first conductive layer and the second conductive layer, the third conductive layer includes a second conductive part, an orthographic projection, on the base substrate, of the second conductive part is at least partially overlapped with an orthographic projection, on the base substrate, of the first conductive part, and the second conductive part is configured to form a second electrode of the capacitor.

In an embodiment of the present disclosure, the first conductive layer includes: a first conductive sub-layer, provided on a side of the base substrate; a second conductive sub-layer, provided on a side, away from the base substrate, of the first conductive sub-layer; and a third conductive sub-layer, provided on a side, away from the base substrate, of the second conductive sub-layer, wherein an activity of a material of the second conductive sub-layer is higher than that of a material of the first conductive sub-layer and that of a material of the third conductive sub-layer. The third conductive layer includes: a fourth conductive sub-layer, provided between the first conductive layer and the second conductive layer; a fifth conductive sub-layer, provided between the fourth conductive sub-layer and the second conductive layer; and a sixth conductive sub-layer, provided between the fifth conductive sub-layer and the second conductive layer, wherein an activity of a material of the fifth conductive sub-layer is higher than that of a material of the fourth conductive sub-layer and that of a material of the sixth conductive sub-layer.

In an embodiment of the present disclosure, the materials of the first conductive sub-layer and the fifth conductive sub-layer are copper, and the materials of the second conductive sub-layer, the third conductive sub-layer, the fourth conductive sub-layer and the sixth conductive sub-layer are molybdenum-nickel alloy.

In an embodiment of the present disclosure, the filter further includes: a first seed layer, provided adjacent to a side, facing the base substrate, of the second conductive layer, and configured as a seed layer for generating the second conductive layer; and a second seed layer, provided between the conductive pillar and a sidewall of the through-hole, and configured as a seed layer for generating the conductive pillar.

In an embodiment of the present disclosure, the filter further includes: a fourth conductive layer, provided on a side, away from the first conductive layer, of the base substrate, and including a plurality of third conductive wires, the third conductive wire being connected between two conductive pillars.

In an embodiment of the present disclosure, the plurality of conductive pillars includes a plurality of first conductive pillars and a plurality of second conductive pillars, the plurality of first conductive pillars are spaced apart in a same direction as a direction in which the plurality of second conductive pillars are spaced apart, and the first conductive pillar and the second conductive pillar are provided in a row; the third conductive wire is connected between the first conductive pillar and the second conductive pillar in a same row; the first conductive wire is connected between the first conductive pillar and the second conductive pillar in adjacent rows, and each of the conductive pillars is connected to one of the first conductive wires.

In an embodiment of the present disclosure, the filter further includes: a third seed layer, provided adjacent to a side, facing the base substrate, of the fourth conductive layer, and configured as a seed layer for generating the fourth conductive layer.

An aspect of the present disclosure provides a method for manufacturing a filter including a first inductor, wherein the method includes:
providing a base substrate;
forming, on the base substrate, a plurality of through-holes passing through the base substrate;
forming conductive pillars within the through-holes, the conductive pillars being configured to form a portion of the first inductor coil;
forming a first conductive layer on a side of the base substrate, the first conductive layer including a plurality of first conductive wires, the first conductive wire being connected between two of the conductive pillars, and the first conductive wires being configured to form a portion of the first inductor coil; and
forming a second conductive layer on a side, away from the base substrate, of the first conductive layer, the second conductive layer including second conductive wires, the second conductive wires corresponding to the first conductive wires respectively, and the second conductive wire being connected to the first conductive wire corresponding thereto through a via-hole.

In an embodiment of the present disclosure, forming, on the base substrate, the plurality of through-holes passing through the base substrate includes:
modifying molecular bonds at predetermined locations of the base substrate by irradiating the predetermined locations with laser; and
forming the through-holes by etching the predetermined locations of the base substrate with an etching solution, wherein a rate that the etching solution etches the predetermined locations is greater than a rate that the etching solution etches other locations of the base substrate.

In an embodiment of the present disclosure, forming the conductive pillars within the through-holes includes:
depositing a second adhesive material layer on an entire side of the base substrate, wherein the second adhesive material layer covers sidewalls of the through-holes and the side of the base substrate;
forming a second seed material layer on a side, away from the base substrate, of the second adhesive material layer; and
forming a conductive material layer on a side, away from the base substrate, of the second seed material layer, wherein the conductive material layer provided within the through-hole forms the conductive pillar.

In an embodiment of the present disclosure, forming the first conductive layer on the side of the base substrate includes:
forming a first conductive material sub-layer on the side of the base substrate using a magnetron sputtering process;
forming a second conductive material sub-layer on a side, away from the base substrate, of the first conductive material sub-layer using the magnetron sputtering process; and
forming a third conductive material sub-layer on a side, away from the base substrate, of the second conductive material sub-layer using the magnetron sputtering process, wherein the first conductive material sub-layer, the second conductive material sub-layer, and the third conductive material sub-layer form a first conductive material layer, and an activity of a material of the second conductive material sub-layer is higher than that of a material of the first conductive material sub-layer and that of a material of the third conductive material sub-layer; and
forming the first conductive layer by patterning the first conductive material layer.

In an embodiment of the present disclosure, forming the second conductive layer on the side, away from the base substrate, of the first conductive layer includes:
forming a first adhesive material layer on the side, away from the base substrate, of the first conductive layer, and forming a first seed material layer on a side, away from the base substrate, of the first adhesive material layer;
forming a first seed layer by patterning the first seed material layer; and
forming the second conductive layer on a side, away from the base substrate, of the first seed layer.

In an embodiment of the present disclosure, the filter further includes a capacitor having a first electrode connecting to a first terminal of the first inductor, the first conductive layer further includes:
a first conductive part, connected to the first conductive wire and configured to form the first electrode of the capacitor,
before forming the second conductive layer on the side, away from the base substrate, of the first conductive layer, the method further includes:
forming a fourth conductive material sub-layer on the side of the base substrate using a magnetron sputtering process;
forming a fifth conductive material sub-layer on a side, away from the base substrate, of the fourth conductive material sub-layer using the magnetron sputtering process;
forming a sixth conductive material sub-layer on a side, away from the base substrate, of the fifth conductive material sub-layer using the magnetron sputtering process, wherein the fourth conductive material sub-layer, the fifth conductive material sub-layer, and the sixth conductive material sub-layer form a third conductive material layer, and an activity of a material of the fifth conductive material sub-layer is higher than that of a material of the fourth conductive material sub-layer and that of a material of the sixth conductive material sub-layer; and
forming the third conductive layer by patterning the third conductive material layer,
wherein the third conductive layer includes a second conductive part, an orthographic projection, on the base substrate, of the second conductive part is at least partially overlapped with an orthographic projection, on the base substrate, of the first conductive part, and the second conductive part is configured to form a second electrode of the capacitor.

In an embodiment of the present disclosure, the plurality of conductive pillars includes a plurality of first conductive pillars and a plurality of second conductive pillars, the plurality of first conductive pillars are spaced apart in a same direction as a direction in which the plurality of second conductive pillars are spaced apart, and the first conductive pillar and the second conductive pillar are provided in a row, the method further includes:
forming a third adhesive material layer on an entire side, away from the first conductive layer, of the base substrate;
forming a third seed material layer on a side, away from the base substrate, of the third adhesive material layer;
forming a fourth conductive material layer on a side, away from the base substrate, of the third seed material layer; and
forming a fourth conductive layer by patterning the fourth conductive material layer,
wherein the fourth conductive layer includes a plurality of third conductive wires, the third conductive wire is connected between the first conductive pillar and the second conductive pillar in a same row, and the first conductive wire is connected between the first conductive pillar and the second conductive pillar in adjacent rows, and each of the conductive pillars is connected to one of the first conductive wires.

In an embodiment of the present disclosure, forming the first conductive layer on the side of the base substrate includes:
forming the first conductive layer by patterning the conductive material layer formed on the side of the base substrate.

In an embodiment of the present disclosure, a thickness of the first conductive layer is less than a thickness of the second conductive layer.

In an embodiment of the present disclosure, the conductive pillar is a hollow conductive pillar, and an extension direction of a cavity in the conductive pillar is the same as an extension direction of the conductive pillar.

In an embodiment of the present disclosure, the method further includes:
filling a support pillar in the cavity of the hollow conductive pillar, wherein the support pillar has a coefficient of thermal expansion between a coefficient of thermal expansion of the conductive pillar and a coefficient of thermal expansion of the base substrate.

In an embodiment of the present disclosure, an orthographic projection, on the base substrate, of the second conductive wire falls on an orthographic projection, on the base substrate, of the first conductive wire.

In an embodiment of the present disclosure, a gap is provided between at least a portion, facing the first conductive layer, of the conductive pillar and the first conductive layer.

An embodiment of the present disclosure provides an electronic device including the filter described above.

It is to be understood that the above general description and the following detailed description are only exemplary and illustrate, and do not intend to limit the present disclosure.

### BRIEF DESCRIPTION OF THE DRAWINGS

The accompanying drawings herein are incorporated into and form a part of the specification, illustrate embodiments consistent with the present disclosure, and are used in conjunction with the specification to explain the principle of the present disclosure. Obviously, the accompanying drawings in the following description are only some of the embodiments of the present disclosure, and those skilled in the art may obtain other accompanying drawings from these drawings without creative work.

FIG. 1 is an equivalent circuit diagram of a filter of the present disclosure;

FIG. 2 is a structural layout of a filter according to an embodiment of the present disclosure;

FIG. 3 is a layout structure of a base substrate in FIG. 2;

FIG. 4 is a layout structure of a fourth conductive layer in FIG. 2;

FIG. 5 is a layout structure of a first conductive layer in FIG. 2;

FIG. 6 is a layout structure of a third conductive layer in FIG. 2;

FIG. 7 is a layout structure of a second conductive layer in FIG. 2;

FIG. 8 is a layout structure of a solder ball layer in FIG. 2;

FIG. 9 is a layout structure of the fourth conductive layer and the base substrate in FIG. 2;

FIG. 10 is a layout structure of the base substrate and the first conductive layer in FIG. 2;

FIG. 11 is a layout structure of the base substrate, the first conductive layer and the third conductive layer in FIG. 2;

FIG. 12 is a layout structure of the base substrate, the first conductive layer, the third conductive layer, and the second conductive layer in FIG. 2;

FIG. 13 is a sectional view of a portion of the filter of FIG. 2 taking along dashed line AA;

FIG. 14 is a schematic structure diagram of a filter according to another embodiment of the present disclosure;

FIG. 15 is a schematic structure diagram of a filter according to another embodiment of the present disclosure; and

FIGS. 16 to 28 is a process flow diagram of a method for manufacturing a filler according an embodiment of the present disclosure.

### DETAILED DESCRIPTION

Example embodiments will now be described more fully with reference to the accompanying drawings. However, the example embodiments can be implemented in a variety of forms and should not be construed as being limited to the examples set forth herein; rather, these embodiments are provided so that the present disclosure is more comprehensive and complete and the concept of the example embodiments is conveyed comprehensively to those skilled in the art. The same reference numerals in the drawings indicate the same or similar structures, and thus detailed descriptions thereof will be omitted.

The terms “a”, “an”, “said” are used to indicate the presence of one or more elements/components/etc.; and the terms “comprising” and “having” are used to indicate an open-ended meaning and mean that there may be an additional element/component/etc. in addition to the listed element/component/etc.

As the electronic product is miniaturized in the current market, a terminal product such as mobile phone, tablet PC, wearable device, and other electronic product has higher requirements for miniaturization of a passive device. Currently, the passive device such as capacitor, inductor and resistor occupies about 70% of the area of a circuit board, and the integrated passive device technology can reduce the area of the passive device by more than 80%. Based on different substrates, the integrated passive device technology may be divided into silicon-based, low-temperature co-fired ceramic-based, glass-based and other technologies.

The current low-temperature co-fired ceramic-based passive device forms a dielectric layer by laminating uncoated ceramic, which is a thick film process. In this process, high-temperature sintering is performed at 1000° C. As the high-temperature sintering may cause a shrinkage problem in the process, there are high requirements for the ceramic material and sintering process. A wire is formed by printing metal paste, which has a conventional line width of 75 μm or more, and thus a fine wire cannot be achieved. A ceramic layer is used as a capacitance dielectric layer, which has a thickness of 10-100 μm. For example, when a relative dielectric constant of the ceramic is 7, and the ceramic layer has a thickness of 10 μm, according to the capacitance formula, a total electrode area of 160 mm² is required in order to achieve a capacitance tolerance of 1 nF. Therefore in order to achieve a small size, it is often necessary to stack the capacitance layers, which leads to an increase in the thickness of the device and thus a larger size of the device.

The manufacturing of a glass-based integrated LC filter is a thin-film process, a line width of more than 3 μm may be achieved based on a photo process, and a thickness of each film layer is also significantly smaller than that of the low-temperature co-fired ceramic-based device. The glass-based integrated LC filter may use silicon nitride as a capacitance dielectric layer, and a thickness of silicon nitride may be 120 nm. For example, when a relative dielectric constant of silicon nitride is 7, only a capacitive area of 2 mm² is required in order to achieve a capacitance of 1 nF, which makes it easy to realize miniaturization of the device compared to the low-temperature co-fired ceramic-based technology. Further, as the film layers to be manufactured is reduced, an alignment accuracy between the glass-based layers is higher.

However, a conductive wire formed on a glass substrate may be detached from the glass substrate since there is a large difference between the coefficient of thermal expansion of the conductive wire and that of the glass substrate.

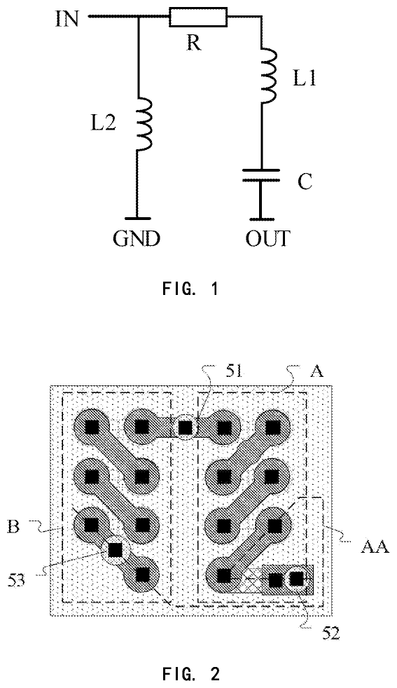

An embodiment first provides a filter, as shown in FIG. 1, which is an equivalent circuit diagram of a filter of the present disclosure. The filter may include a capacitor C, a first inductor L1, a second inductor L2, and a resistor R. A first terminal of the first inductor L1 is connected to a first electrode of the capacitor C, and a second terminal of the first inductor L1 is connected to a signal input terminal IN through the resistor R. A second electrode of the capacitor C is connected to a signal output terminal OUT. The second inductor L2 is connected between the signal input terminal IN and a ground terminal GND.

The filter may also include: a base substrate; a first conductive layer, a third conductive layer, a second conductive layer and a solder ball layer sequentially stacked on a side of the base substrate; and a fourth conductive layer provided on the other side of the base substrate.

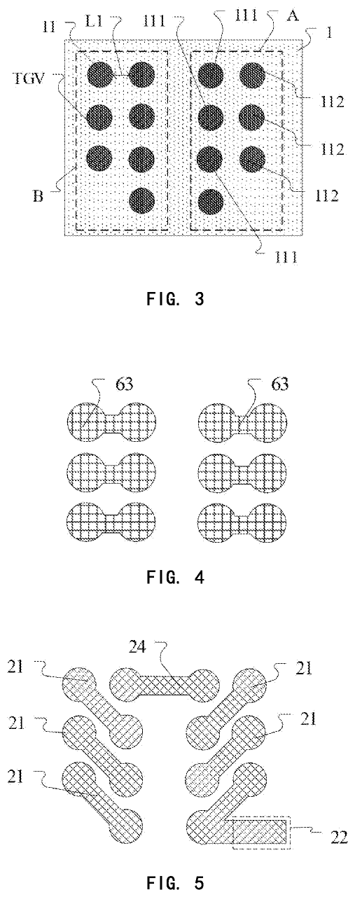

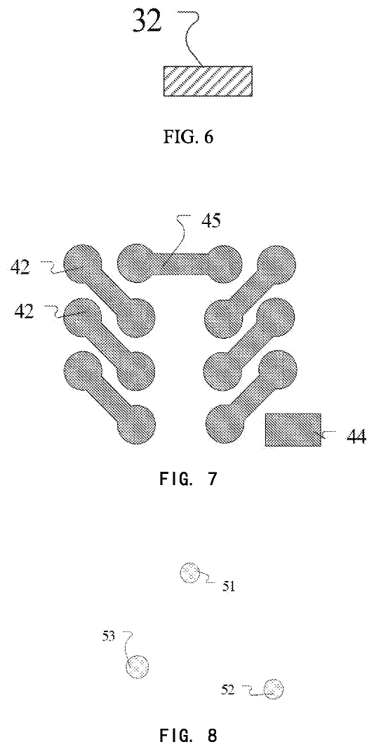

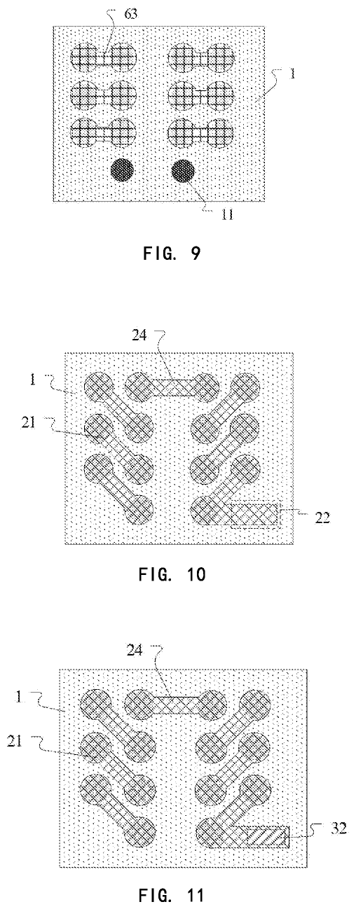

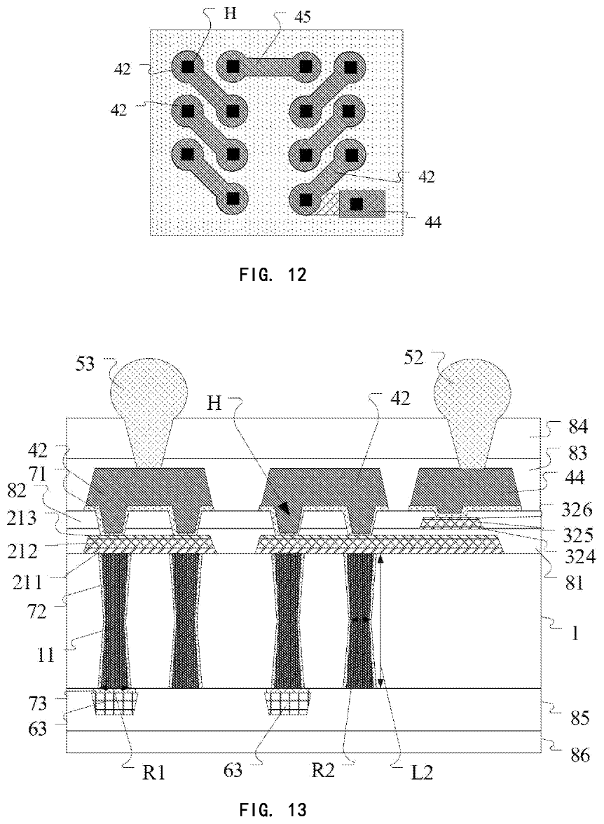

As shown in FIGS. 2-12, FIG. 2 is a structural layout of a filter according to an embodiment of the present disclosure; FIG. 3 is a layout structure of a base substrate in FIG. 2; FIG. 4 is a layout structure of a fourth conductive layer in FIG. 2; FIG. 5 is a layout structure of a first conductive layer in FIG. 2; FIG. 6 is a layout structure of a third conductive layer in FIG. 2; FIG. 7 is a layout structure of a second conductive layer in FIG. 2; FIG. 8 is a layout structure of a solder ball layer in FIG. 2; FIG. 9 is a layout structure of the fourth conductive layer and the base substrate in FIG. 2; FIG. 10 is a layout structure of the base substrate and the first conductive layer in FIG. 2; FIG. 11 is a layout structure of the base substrate, the first conductive layer and the third conductive layer in FIG. 2; and FIG. 12 is a layout structure of the base substrate, the first conductive layer, the third conductive layer, and the second conductive layer in FIG. 2.

As shown in FIGS. 2 and 3, a base substrate 1 is provided with a plurality of through-holes TGV passing through the base substrate 1, the through-holes TGV are filled with conductive material, and the conductive material in the through-holes TGV forms conductive pillars 11. As shown in FIG. 3, the conductive pillars in a region A on the base substrate are used to form a portion of a winding of the first inductor L1, and the conductive pillars in a region B on the base substrate are used to form a portion of a winding of the second inductor L2. In the region A, the plurality of the conductive pillars 11 may include a plurality of first conductive pillars 111 and a plurality of second conductive pillars 112, the plurality of first conductive pillars 111 are spaced apart in a same direction as a direction in which the plurality of second conductive pillars 112 are spaced apart, and the first conductive pillar 111 and the second conductive pillar 112 are provided in a row. In the region B, the plurality of the conductive pillars 11 may likewise include a plurality of first conductive pillars 111 and a plurality of second conductive pillars 112, the plurality of first conductive pillars 111 are spaced apart in a same direction as a direction in which the plurality of second conductive pillars 112 are spaced apart, and the first conductive pillar 111 and the second conductive pillar 112 are provided in a row.

As shown in FIGS. 2, 4, 9, a fourth conductive layer may include a plurality of third conductive wires 63, and the third conductive wire 63 may be connected between the first conductive pillar 111 and the second conductive pillar 112 in the same row. The third conductive wires 63 in the region A may be used to form a portion of the winding of the first inductor L1 and the third conductive wires 63 in the region B may be used to form a portion of the winding of the second inductor L2.

As shown in FIGS. 2, 5, 10, a first conductive layer may include a plurality of first conductive wires 21, the first conductive wire 21 is connected between the first conductive pillar 111 and the second conductive pillar 112 in an adjacent row, and each conductive pillar 11 is connected to one of the first conductive wires 21. In the region A, the first conductive wires 21, the first conductive pillars 111, the second conductive pillars 112, and the third conductive wires 63 may form a winding that extends spirally in a direction in which the conductive pillars 11 are arranged, and the spiral winding may form the first inductor L1, and in the region B, the first conductive wires 21, the first conductive pillars 111, the second conductive pillars 112, and the third conductive wires 63 may form a winding that extends spirally in a direction in which the conductive pillars 11 are arranged, and the spiral winding may form the second inductor L2. As shown in FIGS. 5, 10, the first conductive layer also may include a fourth conductive wire 24, the fourth conductive wire 24 may be used to connect the first inductor L1 and the second inductor L2. The first conductive layer may also include a first conductive part 22, the first conductive part 22 is connected to the first conductive wire 21, and the first conductive part 22 may be used to form a first electrode for the capacitor C.

As shown in FIG. 10, an orthographic projection of the first conductive layer on the base substrate may cover an orthographic projection of the through-hole TGV on the base substrate 1, and an edge of the orthographic projection of the first conductive layer on the base substrate may exceed an edge of the orthographic projection of the through-hole TGV on the base substrate 1 by 5 μm to 10 μm, e.g., the edge of the orthographic projection of the first conductive layer on the base substrate may exceed the edge of the orthographic projection of the through-hole TGV on the base substrate 1 by 5 μm, 7 μm, 9 μm, 10 μm. Such arrangement may improve the reliability of the connection between the first conductive layer and the through-hole.

As shown in FIGS. 2, 6, and 11, a third conductive layer may include a second conductive part 32, an orthographic projection of the second conductive part 32 on the base substrate may be overlapped with an orthographic projection of the first conductive part 22 on the base substrate, and the second conductive part 32 may be used to form a second electrode of the capacitor C. The orthographic projection of the second conductive part 32 on the base substrate may be within the orthographic projection of the first conductive part 22 on the base substrate.

As shown in FIGS. 2, 7, 12, a second conductive layer may include a plurality of second conductive wires 42, and the second conductive wire 42 may be connected to the first conductive wire 21 through a via-hole H. As shown in FIGS. 2, 12, the black square in the drawings denote the location of the via-hole. As shown in FIG. 12, the second conductive wire 42 may be connected to the first conductive wire 21 through the plurality of via-holes. As shown in FIGS. 2, 7, 12, the second conductive layer may further include a fifth conductive wire 45, and a connection part 44. The fifth conductive wire 45 may be connected to the fourth conductive wire 24 through a via-hole. The connection part 44 is connected to the second conductive part 32 through a via-hole. An orthographic projection of the second conductive wire 42 may be overlapped with the orthographic projection of the first conductive wire 21 on the base substrate, for example, the orthographic projection of the second conductive wire 42 on the base substrate may fall on the orthographic projection of the first conductive wire 21 on the base substrate, i.e., the orthographic projection of the second conductive wire 42 on the base substrate is within the orthographic projection of the first conductive wire 21 on the base substrate, or the orthographic projection of the second conductive wire 42 on the base substrate and the orthographic projection of the first conductive wire 21 on the base substrate may be coincided with each other. Such arrangement can reduce the layout area of the filter.

As shown in FIGS. 2, 8, a solder ball layer may include a first solder ball 51, a second solder ball 52, and a third solder ball 53. The first solder ball 51 is connected to the second conductive wire 42 through a via-hole to be connected to the second terminal of the first inductor L1, and the first solder ball 51 may be used for connecting to the signal input terminal IN in FIG. 1. The second solder ball 52 is connected to the connection part 44 for connecting to the second electrode of the capacitor C, and the second solder ball 52 may be used for connecting to the signal output terminal IN in FIG. 1. The third solder ball 53 is connected to the second conductive wire 42 to be connected to the first terminal of the second inductor L2, and the third solder ball 53 may be used for connecting to the ground terminal in FIG. 1.

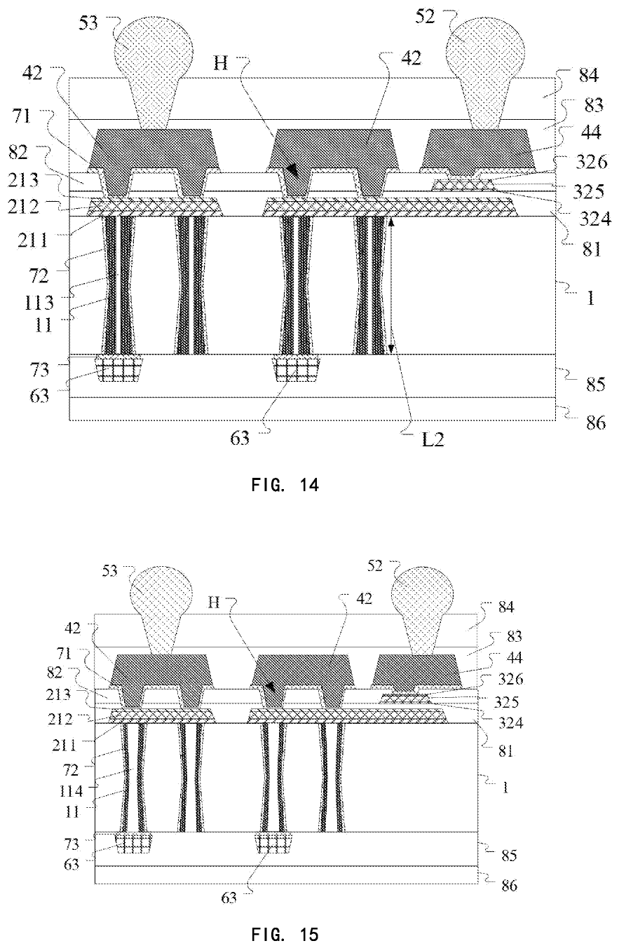

FIG. 13 is a sectional view of a portion of the filter of FIG. 2 taking along dashed line AA. As shown in FIG. 13, the filter may further include a first insulating layer 81, a second insulating layer 82, a third insulating layer 83, a first protective layer 84, a fourth insulating layer 85, a second protective layer 86. The first insulating layer 81 is provided between the first conductive layer and the third conductive layer, the second insulating layer 82 is provided between the second conductive layer and the third conductive layer, the third insulating layer 83 is provided on the side of the second conductive layer away from the base substrate, the first protective layer 84 is provided on the side of the third insulating layer 83 away from the base substrate, the solder ball layer is provided on the side of the first protective layer 84 away from the base substrate, the fourth insulating layer 85 is provided on the side of the fourth conductive layer away from the base substrate, and the second protective layer 86 is provided on the side of the fourth insulating layer 85 away from the base substrate. The material of the first insulating layer 81, the second insulating layer 82, the third insulating layer 83, and the fourth insulating layer 85 may be silicon nitride; the material of the first protective layer 84 may be a polyimide, an acrylic or the like; the material of the second protective layer 86 may be a polyimide, a photoresist or the like; and the base substrate may be a glass substrate. It is to be understood that in other embodiments, the first insulating layer 81, the second insulating layer 82, the third insulating layer 83, the first protective layer 84, the fourth insulating layer 85, the second protective layer 86, and the base substrate may also be formed of other materials. The thickness of the first insulating layer 81 may be 100 nm-130 nm, for example, the thickness of the first insulating layer 81 may be 100 nm, 110 nm, 120 nm, 130 nm, and the like. The thickness of the second insulating layer 82 may be 0.2 μm-0.5 μm, for example, the thickness of the second insulating layer 82 may be 0.2 μm, 0.3 μm, 0.4 μm, 0.5 μm, and the like. The thickness of the third insulating layer 83 may be 0.4 μm-0.6 μm, for example, the thickness of the third insulating layer 83 may be 0.4 μm, 0.5 μm, 0.6 μm, and the like. The thickness of the fourth insulating layer 85 may be 300 nm-500 nm, for example, the thickness of the fourth insulating layer 85 may be 300 nm, 400 nm, 500 nm, and the like. The thickness of the first protective layer 84 may be 2 μm-4 μm, for example, the thickness of the first protective layer 84 may be 2 μm, 3 μm, 4 μm, and the like. The thickness of the second protective layer 86 may be 1 μm-4 μm, for example, the thickness of the second protective layer 86 may be 1 μm, 2 μm, 3 μm, 4 μm, and the like.

As shown in FIG. 13, in an embodiment, the filter is additionally provided with the second conductive layer, and the second conductive wire 42 in the second conductive layer and the first conductive wire 21 in the first conductive layer form a parrel structure, which has a smaller resistance, so that the arrangement can improve the quality factor Q of the inductor and reduce the power consumption of the inductor. In addition, the thickness of the first conductive layer may be reduced by additionally providing the second conductive layer to ensure the quality factor Q of the inductor, and there is a smaller thermal expansion stress between the first conductive layer with a smaller thickness and the base substrate, so that the risk of the detachment of the first conductive layer can be reduced, and the structure stability of the first conductive layer can be improved. It is to be noted that the thermal expansion stress is an interaction force between the first conductive layer and the base substrate due to a difference in the coefficient of thermal expansion of the first conductive layer and the base substrate.

In an embodiment, the thickness of the first conductive layer may be less than the thickness of the second conductive layer. Since the first conductive part 22 in the first conductive layer is further used to form the first electrode for the capacitance C, the deviation of the capacitance value in the LC filter may have a great impact on the center frequency, insertion loss, quality factor or the like, and the flatness of the electrode of the capacitor has a direct impact on the actual value of the capacitance, the first conductive layer needs to have better structural stability performance. In the embodiment, the thickness of the first conductive layer is provided to be smaller than the thickness of the second conductive layer, so that the stability performance of the filter can be improved. In addition, since the second conductive layer is provided on the side of the first conductive layer away from the base substrate, in the process of manufacturing the filter, the manufacturing process of the second conductive layer is after the manufacturing process of the first conductive layer, and the second conductive layer is subjected to fewer high-temperature processes than that of the first conductive layer, so that the thicker second conductive layer can also have better structural stability.

In an embodiment, the thickness of the second conductive layer may be 5-20 times the thickness of the first conductive layer. For example, the thickness of the second conductive layer may be 5 times, 7 times, 8 times, 10 times, 12 times, 14 times, 16 times, 18 times, 20 times, etc., the thickness of the first conductive layer.

It is to be noted that in other embodiments, the equivalent circuit of the filter may also be of other structures, for example, the filter may also be an LC low-pass filter, an LC high-pass filter, an LC high-pass filter of x-type, and the like, and accordingly, the layout structure of the filter may also be of other structures. As long as the filter includes the base substrate and the first conductive layer, the structural stability of the first conductive layer can be improved by additionally providing the second conductive layer.

In an embodiment, as shown in FIGS. 2 and 13, the second conductive wire is connected to the first conductive wire 21 corresponding thereto through two via-holes H. Of the two via-holes H and the two conductive pillars 11 connected to the same first conductive wire 21, the orthographic projection of one conductive pillar 11 on the base substrate and the orthographic projection of one via-hole H on the base substrate are at least partially overlapped with each other, and the orthographic projection of the other conductive pillar 11 on the base substrate and the orthographic projection of the other conductive pillar 11 on the base substrate are at least partially overlapped with each other. This arrangement allows any position on the first conductive wire 21 between the two conductive pillars to be connected in parallel with the second conductive wire 42, which can significantly reduce the resistance of the winding of the inductor.

In an embodiment, as shown in FIG. 13, the filter may further include a second seed layer 72, the second seed layer 72 is provided between the conductive pillar 11 and the sidewall of the through-hole TGV, and the second seed layer 72 may be used as a seed layer for generating the conductive pillar. The material of the conductive pillar 11 may be copper and the material of the second seed layer 72 may be copper. It is to be understood that in other embodiments, a second adhesive layer may also be provided between the second seed layer 72 and the sidewall of the through-hole TGV. The adhesion of the second adhesive layer with the sidewall of the through-hole TGV is stronger than the adhesion of the second seed layer 72 with the sidewall of the through-hole TGV. The second adhesive layer may enable a more stable adhesion of the second seed layer 72 to the sidewall of the through-hole TGV. The second adhesive layer may be a titanium layer.

In an embodiment, the thickness of the base substrate 1 may be 0.25 mm-0.3 mm, for example, the thickness of the base substrate 1 may be 0.25 mm, 0.27 mm, 0.3 mm, and the like. The cross-section of the through-hole TGV in a plane parallel to the base substrate may be circular, and the aperture diameter of the through-hole TGV may be 50 μm-80 μm, e.g., the aperture diameter of the through-hole TGV may be 50 μm, 60 μm, 70 μm, 80 μm. The thickness of the second adhesive layer provided between the second seed layer 72 and the sidewall of the through-hole TGV may be 5 nm-30 nm, e.g., the thickness of the second adhesive layer may be 5 nm, 10 nm, 15 nm, 25 nm, 30 nm, and the like. The thickness of the second seed layer 72 may be 30 nm-80 nm, e.g., the thickness of the second seed layer 72 may be 30 nm, 50 nm, 70 nm, 80 nm, and the like. It is to be understood that in other embodiments, the cross-section of the through-hole TGV in a plane parallel to the base substrate may also be of other shapes, e.g., rectangular, rhombus, or the like.

In an embodiment, the base substrate may be a glass substrate, and the through-hole TGV in the glass substrate may be formed by laser drilling, and accordingly, the aperture areas at various positions of the through-hole TGV may be the same. In addition, the glass substrate may also be formed by a wet etching process, for example, a laser may be used to irradiate predetermined positions on the base substrate 1 to modify the molecular bonds at the predetermined positions of the base substrate, so that the etching rate at the predetermined positions of the base substrate will be greater than the etching rate at other positions of the base substrate, and then an etching solution may be used to etch the predetermined positions of the base substrate to form the through-holes TGV. In an embodiment, the through-hole TGV may be etched from one side of the glass substrate to the other side of the glass substrate using the etching solution, and accordingly, the aperture area of the through-hole TGV gradually decreases from one opening to the other opening. In another embodiment, the through-hole TGV may be etched from both sides of the base substrate to the middle of the base substrate using the etching solution, and accordingly, the aperture area of the through-hole TGV may decrease gradually from both openings to a middle position. The wet etching process may make the sidewall of the through-hole TGV smoother, which may help the second adhesive layer and the second seed layer 72 to be adhered to the sidewall of the through-hole TGV.

In an embodiment, as shown in FIGS. 3 and 13, a minimum distance between adjacent through-holes TGV is L1, a maximum inner diameter of the through-hole TGV is R1, and L1 may be greater than or equal to 2*R1 and less than or equal to 4*R1, for example, L1 may be equal to 2*R1, 3*R1, 4*R1, and the like. The arrangement may allow a sufficient interval between adjacent through-holes TGVs, which can avoid a reduction in the overall structural strength of the filter due to the superposition of the stress zones on the sidewalls of the different through-holes TGV, and furthermore, the arrangement restricts the distance between the adjacent through-holes, thereby avoiding the filter occupying too much space.

Since there is a large difference between a coefficient of thermal expansion of the conductive pillar in the through-hole and that of the base substrate, when the extension length of the through-hole TGV is too large, the conductive pillar in the through-hole has an obvious length change due to the temperature change, which may easily lead to cracks between the conductive pillar and the first conductive layer and the fourth conductive layer. When the extension length of the through-hole TGV is too small, the inductor may occupy a larger layout space in order to ensure a sufficient coil cross-sectional area. In an embodiment, as shown in FIG. 13, the extension length of the through-hole TGV is L2, the minimum inner diameter of the through-hole TGV is R2, and L2 may be greater than or equal to 3*R2 and less than or equal to 7*R2, e.g., L2 may be equal to 3*R2, 5*R2, 7*R2, and the like. This arrangement can greatly reduce the layout area of the inductor while ensuring a stable connection between the conductive pillar 11 and the first conductive layer and the fourth conductive layer.

In an embodiment, as shown in FIG. 13, the first conductive layer may include a first conductive sub-layer 211, a second conductive sub-layer 212, and a third conductive sub-layer 213, the first conductive sub-layer 211 is provided on the side of the base substrate 1, the second conductive sub-layer 212 is provided on the side of the first conductive sub-layer 211 away from the base substrate 1, and the third conductive sub-layer 213 is provided on the side of the second conductive sub-layer 212 away from the base substrate 1. An activity of a material of the second conductive sub-layer 212 is higher than that of a material of the first conductive sub-layer 211 and that of a material of the third conductive sub-layer 213. That is, the oxidation resistance of the first conductive sub-layer 211 and that of the third conductive sub-layer 213 are higher than the oxidation resistance of the second conductive sub-layer 212. In addition, the resistivity of the material of the second conductive sub-layer 212 may be smaller than the resistivity of the material of the first conductive sub-layer 211, and the resistivity of the material of the third conductive sub-layer 213. This arrangement can ensure that the first conductive layer has a small square resistance, and at the same time can prevent, by using the first conductive sub-layer 211 and the third conductive sub-layer 213, the second conductive sub-layer 212 from being oxidized. It is to be noted that since there is a large difference between a coefficient of thermal expansion of the conductive pillar in the through-hole and that of the base substrate, it may easily lead to cracks between the conductive pillar and the first conductive layer. In an embodiment, there is a gap between at least a portion of the conductive pillar facing the first conductive layer and the first conductive layer. The first conductive sub-layer 211 and the third conductive sub-layer 213 may be a molybdenum-nickel alloy layer, and the second conductive sub-layer 212 may be a copper layer. The thickness of the first conductive sub-layer 211 may be 0.03 μm-0.05 μm, for example, the thickness of the first conductive sub-layer 211 may be 0.03 μm, 0.04 μm, 0.05 μm. The thickness of the second conductive sub-layer 212 may be 0.3 μm-0.5 μm, for example, the thickness of the second conductive sub-layer 212 may be 0.3 μm, 0.4 μm, 0.5 μm. The thickness of the third conductive sub-layer 213 may be 0.02 μm-0.05 μm, for example, the thickness of the third conductive sub-layer 213 may be 0.02 μm, 0.03 μm, 0.04 μm, 0.05 μm. It is to be understood that in other embodiments, the first conductive layer and the conductive pillar may also be integrally moulded. When the first conductive layer and the conductive pillar are integrally moulded, it may reduce the risk of poor connection between the conductive pillar 11 and the first conductive layer.

In an embodiment, as shown in FIG. 13, the third conductive layer may include a fourth conductive sub-layer 324, a fifth conductive sub-layer 325, and a sixth conductive sub-layer 326, the fourth conductive sub-layer 324 is provided between the first conductive layer and the second conductive layer, the fifth conductive sub-layer 325 is provided between the fourth conductive sub-layer 324 and the second conductive layer, and the sixth conductive sub-layer 326 is provided between the fifth conductive sub-layer 325 and the second conductive layer. An activity of a material of the fifth conductive sub-layer 325 is higher than that of a material of the fourth conductive sub-layer 324 and that of a material of the sixth conductive sub-layer 326. In addition, the resistivity of the material of the fifth conductive sub-layer 325 may be smaller than the resistivity of the material of the fourth conductive sub-layer 324, and the resistivity of the material of the sixth conductive sub-layer 326. This arrangement can ensure that the third conductive layer has a smaller square resistance, and at the same time, can prevent, by using the fourth conductive sub-layer 324 and the sixth conductive sub-layer 326, the fifth conductive sub-layer 325 from being oxidized. The fourth conductive sub-layer 324 and the sixth conductive sub-layer 326 may be a molybdenum-nickel alloy layer, and the fifth conductive sub-layer 325 may be a copper layer. The thickness of the fourth conductive sub-layer 324 may be 0.03 μm-0.05 μm, for example, the thickness of the fourth conductive sub-layer 324 may be 0.03 μm, 0.04 μm, 0.05 μm. The thickness of the fifth conductive sub-layer 325 may be 0.2 μm-0.5 μm, for example, the thickness of the fifth conductive sub-layer 325 may be 0.2 μm, 0.3 μm, 0.4 μm, 0.5 μm. The thickness of the sixth conductive sub-layer 326 may be 0.02 μm-0.05 μm, for example, the thickness of the sixth conductive sub-layer 326 may be 0.02 μm, 0.03 μm, 0.04 μm, 0.05 μm.

In an embodiment, as shown in FIG. 13, the filter may further include a first seed layer 71, and the first seed layer 71 is provided adjacent to the side of the second conductive layer facing the base substrate 1, i.e., the first seed layer 71 is in contact with the second conductive layer. The first seed layer 71 is used as a seed layer for generating the second conductive layer. In other embodiments, a first adhesive layer may also be provided between the first seed layer 71 and the first insulating layer 81, the second insulating layer 82, and the first conductive layer. The adhesion of the first adhesive layer with the first insulating layer 81 and the second insulating layer 82 is better than the adhesion of the first seed layer 71 with the first insulating layer 81 and the second insulating layer 82. The first adhesive layer may be a molybdenum-nickel alloy layer, and the first seed layer 71 may be a copper layer. The thickness of the first adhesive layer may be 0.03 μm-0.05 μm, for example, the thickness of the first adhesive layer may be 0.03 μm, 0.04 μm, 0.05 μm. The thickness of the first seed layer 71 may be 0.2 μm-0.5 μm, for example, the thickness of the first seed layer 71 may be 0.2 μm, 0.3 μm, 0.4 μm, 0.5 μm. The thickness of the second conductive layer may be 5 μm-10 μm, e.g., the thickness of the second conductive layer may be 5 μm, 6 μm, 8 μm, 10 μm. The thicker second conductive layer may improve the quality factor Q of the inductor and reduce the power consumption of the inductor.

In an embodiment, as shown in FIG. 13, the filter may further include a third seed layer 73, the third seed layer 73 is provided adjacent to the side of the fourth conductive layer facing the base substrate 1, and the third seed layer is used as a seed layer for generating the fourth conductive layer. In other embodiments, a third adhesive layer may also be provided between the third seed layer 73 and the base substrate 1. The adhesion of the third adhesive layer with the base substrate 1 is better than the adhesion of the third seed layer 73 with the base substrate 1. The third adhesive layer may be a molybdenum-nickel alloy layer, and the thickness of the third adhesive layer may be 0.03 μm-0.05 μm, for example, the thickness of the third adhesive layer may be 0.03 μm, 0.04 μm, 0.05 μm. The third seed layer 73 may be a copper layer, and the thickness of the third seed layer 73 may be 0.2 μm-0.5 μm, e.g., the thickness of the third seed layer 73 may be 0.2 μm, 0.3 μm, 0.4 μm, 0.5 μm. The thickness of the fourth conductive layer may be 5 μm-10 μm, for example, the thickness of the fourth conductive layer may be 5 μm, 6 μm, 8 μm, 10 μm. The thicker fourth conductive layer may improve the quality factor Q of the inductor and reduce the power consumption of the inductor.

As shown in FIG. 14, it is a schematic structure diagram of a filter according to another embodiment of the present disclosure. Compared to FIG. 13, the conductive pillar 11 in the filter shown in FIG. 14 may be a hollow conductive pillar, and an extension direction of a cavity 113 of the conductive pillar may be the same as the extension direction of the conductive pillar 11. The cavity 113 may pass through the entire conductive pillar 11. This arrangement may reduce the amount of thermal expansion of the conductive pillar 11, which may reduce the risk of fracture of the conductive pillar with the first conductive layer and the fourth conductive layer due to the difference between the coefficient of thermal expansion of the conductive pillar and the coefficient of thermal expansion of the base substrate. In an embodiment, the thickness of the sidewall of the conductive pillar may be 5 μm-10 μm, for example, the thickness of the sidewall of the conductive pillar may be 5 μm, 6 μm, 7 μm, 8 μm, 9 μm, 10 μm.

In other embodiments, as shown in FIG. 15, it is a schematic structure diagram of a filter according to another embodiment of the present disclosure. The filter further includes a support pillar 114. The support pillar 114 may be filled in the cavity of the hollow conductive pillar, and the coefficient of thermal expansion of the support pillar 114 is between the coefficient of thermal expansion of the conductive pillar 11 and the coefficient of thermal expansion of the base substrate 1. The support pillar 114 can not only similarly reduce the risk of fracture of the conductive pillar with the first conductive layer and the fourth conductive layer due to the difference between the coefficient of thermal expansion of the conductive pillar and the coefficient of thermal expansion of the base substrate, but also can improve the overall strength of the filter. The material of the support pillar may be a resin material.

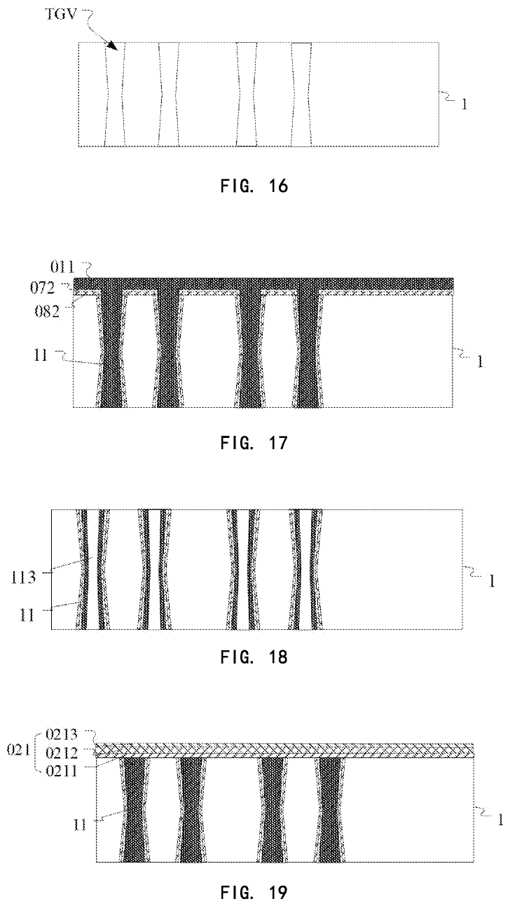

An embodiment also provides a method for manufacturing the filter shown in FIG. 13. FIGS. 16 to 28 is a process flow diagram of a method for manufacturing a filler according an embodiment of the present disclosure, and as shown in FIGS. 16-28, the method includes the following steps.

In step S1, as shown in FIG. 16, a base substrate 1 is provided and a plurality of through-holes TGV passing through the base substrate 1 are formed in the base substrate 1. The base substrate 1 may be a glass substrate, and the thickness of the glass base substrate may be 0.25 mm-0.3 mm, e.g., the thickness of the glass substrate may be 0.25 mm, 0.27 mm, 0.3 mm and the like. The aperture diameter of the through-hole TGV may be 50 μm-80 μm, for example, the aperture diameter of the through-hole TGV may be 50 μm, 60 μm, 70 μm, 80 μm. In an embodiment, the through-hole TGV may be formed by using laser drilling or laser-induced etching. The thermal effect of the laser drilling may make the roughness of the inside wall of the through-hole TGV larger, which will affect the sputtering of the film layer inside the through-hole TGV and weaken the bonding force between the film layer in the through-hole and the wall of the through-hole, the laser drilling is detrimental to the preparation of highly dense adhesive layer and seed layer inside the through-hole. The laser-induced etching method may include: modifying molecular bonds at predetermined locations of the base substrate 1 by irradiating the predetermined locations of the base substrate 1 with laser, so that the etching rate at the predetermined positions of the base substrate is greater than the etching rate at other positions of the base substrate; and then forming the through-holes TGV by etching the predetermined locations of the base substrate with an etching solution. The etching solution may be a mixed solution of hydrofluoric acid and nitric acid, a mixed solution of sodium hydroxide and citric acid, or the like. The etching solution may be used to etch the through-hole TGV from both sides of the glass substrate to the middle of the glass substrate, and accordingly, the aperture area of the through-hole TGV may gradually decrease from the two openings towards the middle position. The wet etching process can make the sidewall of the through-hole TGV smoother, which can help the subsequent adhesive layer and the seed layer to be adhered to the sidewall of the through-hole TGV.

In step S2, a conductive pillar is formed in the through-hole TGV. As shown in FIG. 17, a second adhesive material layer 082 may be deposited on the side of the base substrate 1 using a magnetron sputtering process. The second adhesive material layer 082 covers the sidewall of the through-hole TGV and the entire side of the base substrate 1. Then a second seed material layer 072 is formed on the side of the second adhesive material layer 082 away from the base substrate 1. The second seed material layer 072 similarly covers the sidewall of the through-hole TGV and the side of the base substrate 1. Then, the through-hole TGV is filled by using double plating in a butterfly fashion to form the conductive pillar 11 in the through-hole TGV. At the same time, a conductive material layer 011 is also generated on the second seed material layer 072 on the side of the base substrate. As shown in FIG. 18, a chemical-mechanical polishing method may also be utilized to remove the excess conductive layer 011 from the surface of the base substrate 1 for subsequent film layer fabrication. The second adhesive material layer 082 may be a titanium layer, and the thickness of the second adhesive material layer 082 may be 5 nm-30 nm, for example, the thickness of the second adhesive material layer 082 may be 5 nm, 10 nm, 15 nm, 25 nm, 30 nm, and the like. The thickness of the second seed material layer 072 may be 30 nm-80 nm, for example, the thickness of the second seed material layer 072 may be 30 nm, 50 nm, 70 nm, 80 nm, and the like. In other embodiments, as shown in FIG. 19, the conductive pillar 11 may also be perforated so that the conductive pillar forms a hollow conductive pillar. A cavity 113 of the hollow conductive pillar may also be filled with a material such as a resin, and a coefficient of thermal expansion of the material filled in the cavity 113 may be between the coefficient of thermal expansion of the conductive pillar 11 and the coefficient of thermal expansion of the base substrate. It is to be understood that in other embodiments, the conductive pillar may be formed in the through-hole TGV in other ways, for example, the conductive pillar may be formed in the through-hole TGV by filling with a conductive material, a copper-core solder ball, and the like.

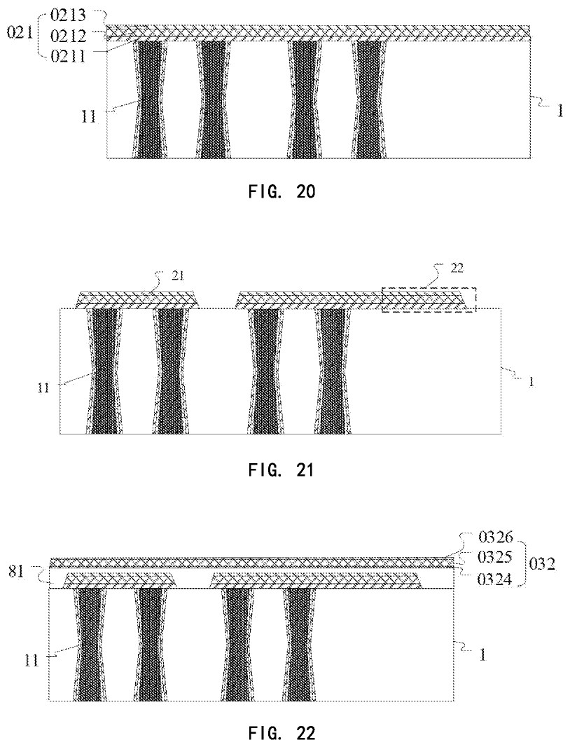

In step S3, a first conductive layer is formed on a side of the base substrate. As shown in FIG. 20, a first conductive material sub-layer 0211 may be formed on the side of the base substrate 1 using a magnetron sputtering process; a second conductive material sub-layer 0212 may be formed on the side of the first conductive material sub-layer 0211 away from the base substrate 1 using a magnetron sputtering process; and a third conductive material sub-layer 0213 may be formed on the side of the second conductive material sub-layer 0212 away from the base substrate 1 using a magnetron sputtering process. The first conductive material sub-layer 0211, the second conductive material sub-layer 0212, and the third conductive material sub-layer 0213 form a first conductive material layer 021. An activity of a material of the second conductive material sub-layer 0212 is higher than that of a material of the first conductive material sub-layer 0211 and that of a material of the third conductive material sub-layer 0213. Furthermore, the resistivity of the material of the second conductive material sub-layer 0212 may be smaller than the resistivity of the material of the first conductive material sub-layer 0211 and the resistivity of the material of the third conductive material sub-layer 0213. As shown in FIG. 21, the first conductive layer may be formed by patterning the first conductive material layer 021. The first conductive layer may include a first conductive wire 21 and a first conductive part 22, and the first conductive part 22 may be used to form a first electrode of the capacitor. In an embodiment, a flat first conductive layer may be formed by using the magnetron sputtering process, which can ensure a more accurate capacitance value of the capacitor. The first conductive material sub-layer 0211 and the third conductive material sub-layer 0213 may be a molybdenum-nickel alloy layer, and the second conductive material sub-layer 0212 may be a copper layer. The thickness of the first conductive material sub-layer 0211 may be 0.03 μm-0.05 μm, for example, the thickness of the first conductive material sub-layer 0211 may be 0.03 μm, 0.04 μm, 0.05 μm, and the like. The thickness of the second conductive material sub-layer 0212 may be 0.3 μm-0.5 μm, for example, the thickness of the second conductive material sub-layer 0212 may be 0.3 μm, 0.4 μm, 0.5 μm, and the like. The thickness of the third conductive material sub-layer 0213 may be 0.02 μm-0.05 μm, for example, the thickness of the third conductive material sub-layer 0213 may be 0.02 μm, 0.03 μm, 0.04 μm, 0.05 μm and the like. It is to be understood that in other embodiments, the first conductive layer may also be formed by using the conductive material layer 011 formed on the side of the base substrate 1 in FIG. 17, e.g., a polishing rate of the chemical-mechanical polishing may be controlled to form the conductive material layer 011 on the entire side of the base substrate 1, and then the first conductive layer may be formed by patterning the conductive material layer on the entire side of the base substrate 1 in FIG. 17. The thickness of the conductive layer formed on the entire side/surface may be 1 μm −5 μm, for example, the thickness of the conductive layer formed on the entire surface may be 1 μm, 2 μm, 3 μm, 4 μm, 5 μm. In an embodiment, the patterning process may include exposing, developing, etching, and other processes.

In step S4, as shown in FIG. 22, a first insulating layer 81 may further be formed on a side of the first conductive layer away from the base substrate 1 by using a plasma-enhanced chemical vapor deposition process. The material of the first insulating layer 81 may be silicon nitride, and the thickness of the first insulating layer 81 may be 110-130 nm, for example, the thickness of the first insulating layer 81 may be 110 nm, 120 nm, 130 nm and the like.

When the first insulating layer 81 is deposited using the plasma enhanced chemical vapor deposition, the filter is in a high temperature environment. The solid conductive pillar 11 may have a large thermal expansion, and thus there may be cracks between the solid conductive pillar 11 and the first conductive layer, which in turn affects the electrical connection of the device. The hollow conductive pillar 11 shown in FIG. 19 may reduce the amount of thermal expansion of the conductive pillar 11, thereby helping to solve the technical problem of cracks being present between the conductive pillar 11 and the first conductive layer. Similarly, filling the hollow conductive pillar with a material with a specific coefficient of thermal expansion not only solves the technical problem of cracks being present between the conductive pillar 11 and the first conductive layer, but also improves the overall strength of the filter.

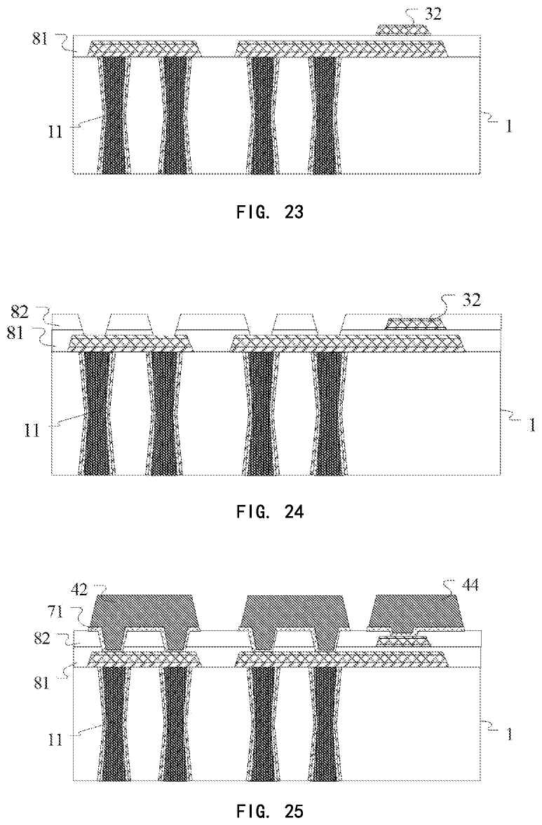

In step S5, as shown in FIG. 22, a third conductive layer may also be formed on the side of the first insulating layer 81 away from the base substrate 1. The third conductive layer may be formed by: forming a fourth conductive material sub-layer 0324 on the side of the base substrate using a magnetron sputtering process; forming a fifth conductive material sub-layer 0325 on the side of the fourth conductive material sub-layer 0324 away from the base substrate using a magnetron sputtering process; and forming a sixth conductive material sub-layer 0326 on the side of the fifth conductive material sub-layer 0325 away from the base substrate using a magnetron sputtering process. The fourth conductive material sub-layer 0324, the fifth conductive material sub-layer 0325 and the sixth conductive material sub-layer 0326 form a third conductive material layer 032, an activity of a material of the fifth conductive material sub-layer 0325 is higher than that of a material of the fourth conductive material sub-layer 0324 and that of a material of the sixth conductive material sub-layer 0326, and the resistivity of the material of the fifth conductive material sub-layer 0325 may be smaller than the resistivity of the material of the fourth conductive material sub-layer 0324, and the resistivity of the material of the sixth conductive material sub-layer 0326. Finally, the third conductive layer is formed by patterning the third conductive material layer 032 as shown in FIG. 23. The third conductive layer includes a second conductive part 32, which may be used to form another electrode of the capacitor C. The fourth conductive material sub-layer 0324 and the sixth conductive material sub-layer 0326 may prevent the fifth conductive material sub-layer 0325 from being oxidized. The fourth conductive material sub-layer 0324 and the sixth conductive material sub-layer 0326 may be a molybdenum-nickel alloy layer, and the fifth conductive material sub-layer 0325 may be a copper layer. The thickness of the fourth conductive material sub-layer 0324 may be 0.03 μm-0.05 μm, for example, the thickness of the fourth conductive material sub-layer 0324 may be 0.03 μm, 0.04 μm, 0.05 μm. The thickness of the fifth conductive material sub-layer 0325 may be 0.2 μm-0.5 μm, for example, the thickness of the fifth conductive material sub-layer 0325 may be 0.2 μm, 0.3 μm, 0.4 μm, 0.5 μm. The thickness of the sixth conductive material sub-layer 0326 may be 0.02 μm-0.05 μm, for example, the thickness of the sixth conductive material sub-layer 0326 may be 0.02 μm, 0.03 μm, 0.04 μm, 0.05 μm.

In step S6, as shown in FIG. 24, a second insulating layer 82 may be formed on the side of the second conductive layer away from the base substrate. The material of the second insulating layer 82 may be silicon nitride, and the thickness of the second insulating layer 82 may be 0.2 μm-0. 5 μm, for example, the thickness of the second insulating layer 82 may be 0.2 μm, 0.30 μm, 0.4 μm, 0.5 μm.

In step S7, as shown in FIG. 24, the first insulating layer 81 and the second insulating layer 82 may be etched at one time using a mask to form via-holes.

In step S8, a second conductive layer is formed on the side of the second insulating layer 82 away from the base substrate 1. A first adhesive material layer may be formed on the side of the second insulating layer 82 away from the base substrate 1, and a first seed material layer may be formed on the side of the first adhesive material layer away from the base substrate 1. As shown in FIG. 25, a first seed layer 71 may be formed by patterning the first seed material layer, and the second conductive layer may be formed on the side of the first seed layer 71 away from the sidewall of the through-hole by using an electroplating process. The second conductive layer may only be generated at a location having the first seed layer 71. The second conductive layer may include a second conductive wire 42 and a connection part 44. The second conductive wire 42 is connected to the first conductive wire 21 through a via-hole in the first insulating layer 81 and the second insulating layer 82. The connection part 44 is connected to the second conductive part 32 through a via-hole in the second insulating layer 82. The first adhering material layer may be a molybdenum-nickel alloy layer, and the first seed material layer may be a copper layer. The thickness of the first adhesive material layer may be 0.03 μm-0.05 μm, for example, the thickness of the first adhesive material layer may be 0.03 μm, 0.04 μm, 0.05 μm. The thickness of the first seed material layer may be 0.2 μm-0.5 μm, for example, the thickness of the first seed material layer may be 0.2 μm, 0.3 μm, 0.4 μm, 0.5 μm. The second conductive layer may be a copper layer, and the thickness of the second conductive layer may be 5 μm −10 μm, for example, the thickness of the second conductive layer may be 5 μm, 6 μm, 8 μm, 10 μm.

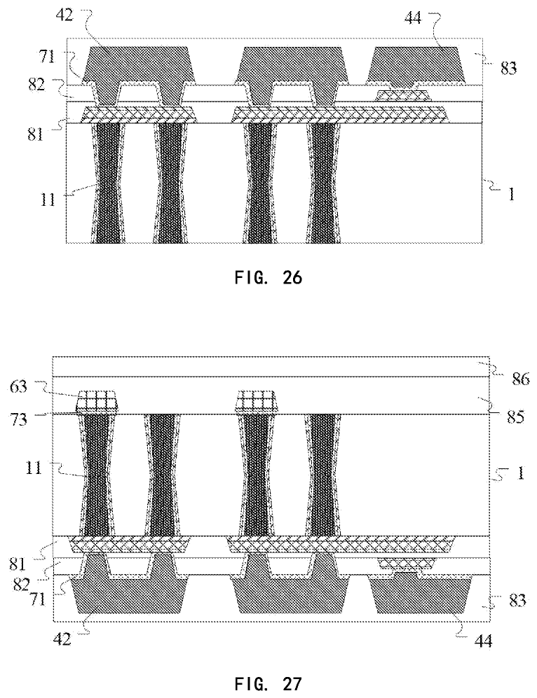

In step S9, as shown in FIG. 26, a third insulating layer 83 is formed on the side of the second conductive layer away from the base substrate. The material of the third insulating layer 83 may be silicon nitride, and the thickness of the third insulating layer 83 may be 0.4 μm-0.6 μm, for example, the thickness of the third insulating layer 83 may be 0.4 μm, 0.5 μm, 0.6 μm, and the like.

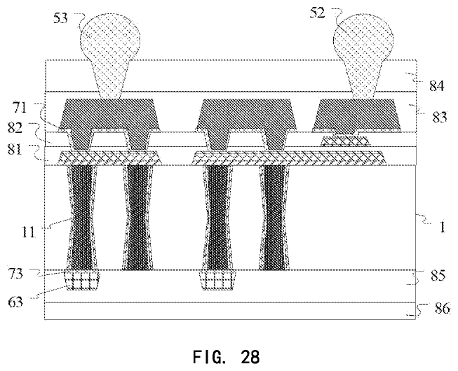

In step S10, as shown in FIG. 27, the device sample is turned over, a third adhesive material layer is formed on the entire side of the base substrate away from the first conductive layer, a third seed material layer is formed on the entire side of the third adhesive material layer away from the base substrate, a fourth conductive material layer is formed on the entire side of the third seed material layer away from the base substrate using an electroplating process, and a fourth conductive layer is formed by patterning the fourth conductive material layer using a patterning process. At the same time, the third adhesive material layer and the third seed material layer are also etched by the same patterning process to have the same pattern as the fourth conductive layer. As shown in FIG. 27, a third seed layer 73 is formed after the third seed material layer is patterned, and the structure of the third adhesive material layer after being patterned is not shown. The fourth conductive layer includes a third conductive wire 63. Furthermore, a fourth insulating layer 85 is formed on a side of the fourth conductive layer away from the base substrate, and the fourth insulating layer 85 may be used to prevent the wiring of the fourth conductive layer from being oxidized. The third adhesive material layer may be a molybdenum-nickel alloy layer, and the thickness of the third adhesive material layer may be 0.03 μm-0.05 μm, for example, the thickness of the third adhesive material layer may be 0.03 μm, 0.04 μm, 0.05 μm. The third seed material layer may be a copper layer, the thickness of the third seed material layer may be 0.2 μm-0.5 μm, and the thickness of the third seed layer 73 may be 0.2 μm, 0.3 μm, 0.4 μm, 0.5 μm. The material of the fourth conductive layer may be copper, and the thickness of the fourth conductive layer may be 5 μm-10 μm, for example, the thickness of the fourth conductive layer may be 5 μm, 6 μm, 8 μm, 10 μm. The material of the fourth insulating layer 85 may be silicon nitride, and the thickness of the fourth insulating layer 85 may be 300 nm-500 nm, for example, the thickness of the fourth insulating layer 85 may be 300 nm, 400 nm, 500 nm, and the like.

In step S11, as shown in FIG. 27, a second protective layer 86 may be spin-coated on the entire side of the fourth insulating layer 85 away from the base substrate. The second protective layer 86 may be used to protect the wiring of the fourth conductive layer to buffer the action of external forces on the fourth conductive layer. The material of the second protective layer 86 may be polyimide, photoresist, and the like, and the thickness of the second protective layer 86 may be 1 μm-4 μm, for example, the thickness of the second protective layer 86 may be 1 μm, 2 μm, 3 μm, 4 μm, and the like.

In step S12, as shown in FIG. 28, the sample device is turned over to the front side, and a first protective layer 84 is spin-coated on the side of the third insulating layer 83 away from the base substrate. Photolithography is performed on the third insulating layer 83 and the first protective layer 84, and ultimately a solder ball layer is formed on the side of the first protective layer 84 away from the base substrate. The material of the first protective layer 84 may be polyimide, acrylic or the like, and the thickness of the first protective layer 84 may be 2 μm-4 μm, for example, the thickness of the first protective layer 84 may be 2 μm, 3 μm, 4 μm, and the like.

An embodiment also provides an electronic device including the filter described above. The electronic device may be a display device.

Those skilled in the art may easily conceive of other embodiments of the present disclosure upon consideration of the specification and practice of the invention disclosed herein. The present disclosure is intended to cover any variations, uses, or adaptations of the present disclosure that follow the general principles of the present disclosure and include the common general knowledge or conventional technical means in the technical field not disclosed by the present disclosure. The specification and embodiments are to be regarded as exemplary only, with the true scope and spirit of the present disclosure being indicated by the following claims.

It is to be understood that the present disclosure is not limited to the precise structures described above and illustrated in the accompanying drawings, and that various modifications and changes may be made without departing from the scope thereof. The scope of the present disclosure is limited only by the appended claims.

1. A filter comprising a first inductor, wherein the filter further comprises:
a base substrate, having a plurality of through-holes passing through the base substrate;
a plurality of conductive pillars, respectively corresponding to the through-holes, the conductive pillar being filled in the through-hole corresponding thereto, and the conductive pillars being configured to form a portion of a coil of the first inductor;
a first conductive layer, provided on a side of the base substrate, the first conductive layer comprising a plurality of first conductive wires, the first conductive wire being connected between two of the conductive pillars, and the first conductive wires being configured to form a portion of the coil of the first inductor; and
a second conductive layer, provided on a side, away from the base substrate, of the first conductive layer, the second conductive layer comprising second conductive wires, the second conductive wires corresponding to the first conductive wires respectively, and the second conductive wire being connected to the first conductive wire corresponding thereto through a via-hole.

2. The filter according to claim 1, wherein a thickness of the first conductive layer is less than a thickness of the second conductive layer.

3. The filter according to claim 2, wherein the thickness of the second conductive layer is 5 to 20 times the thickness of the first conductive layer.

4. The filter according to claim 1, wherein an orthographic projection, on the base substrate, of the second conductive wire falls on an orthographic projection, on the base substrate, of the first conductive wire.

5. The filter according to claim 1, wherein the second conductive wire is connected to the first conductive wire corresponding thereto through a plurality of via-holes,
as for a plurality of via-holes and two conductive pillars connected to a same first conductive wire, an orthographic projection, on the base substrate, of one conductive pillar is at least partially overlapped with an orthographic projection, on the base substrate, of one o via-hole, and an orthographic projection, on the base substrate, of another conductive pillar is at least partially overlapped with an orthographic projection, on the base substrate, of another via-hole.

6. The filter according to claim 1, wherein the first conductive layer and the conductive pillar are integrally moulded.

7. The filter according to claim 1, wherein a gap is provided between at least a portion, facing the first conductive layer, of the conductive pillar and the first conductive layer.

8. The filter according to claim 1, wherein the conductive pillar is a hollow conductive pillar, and an extension direction of a cavity in the conductive pillar is the same as an extension direction of the conductive pillar.

9. The filter according to claim 8, wherein the filter further comprises:
a support pillar, filled within the cavity of the hollow conductive pillar,
wherein the support pillar has a coefficient of thermal expansion between a coefficient of thermal expansion of the conductive pillar and a coefficient of thermal expansion of the base substrate.

10. The filter according to claim 1, wherein the through-hole has a an aperture area in one of the following cases:
the aperture area is the same at various locations;
the aperture area decreases gradually from one side of the base substrate to another side of the base substrate; or
the aperture area decreases gradually from both sides of the base substrate to a middle position of the base substrate.

11. The filter according to claim 1, wherein a minimum distance between adjacent through-holes is L1, the through-hole has a maximum inner diameter of R1, and L1 is greater than or equal to 2*R1.

12. The filter according to claim 1, wherein the through-hole has an extension length of L2 and a minimum inner diameter of R2, and L2 is greater than or equal to 3*R2 and less than or equal to 7*R2.

13. The filter according to claim 1, wherein the filter further comprises a capacitor, and the capacitor has a first electrode connected to a first terminal of the first inductor,
the first conductive layer further comprises:
a first conductive part, connected to the first conductive wire and being configured to form the first electrode of the capacitor,
the filter further comprises:
a third conductive layer, provided between the first conductive layer and the second conductive layer,
the third conductive layer comprises a second conductive part, an orthographic projection, on the base substrate, of the second conductive part is at least partially overlapped with an orthographic projection, on the base substrate, of the first conductive part, and the second conductive part is configured to form a second electrode of the capacitor.

14. The filter according to claim 13, wherein the first conductive layer comprises:
a first conductive sub-layer, provided on a side of the base substrate;
a second conductive sub-layer, provided on a side, away from the base substrate, of the first conductive sub-layer; and
a third conductive sub-layer, provided on a side, away from the base substrate, of the second conductive sub-layer,
wherein an activity of a material of the second conductive sub-layer is higher than that of a material of the first conductive sub-layer and that of a material of the third conductive sub-layer,
the third conductive layer comprises:
a fourth conductive sub-layer, provided between the first conductive layer and the second conductive layer;
a fifth conductive sub-layer, provided between the fourth conductive sub-layer and the second conductive layer; and
a sixth conductive sub-layer, provided between the fifth conductive sub-layer and the second conductive layer,
wherein an activity of a material of the fifth conductive sub-layer is higher than that of a material of the fourth conductive sub-layer and that of a material of the sixth conductive sub-layer.

15. The filter according to claim 14, wherein the materials of the first conductive sub-layer and the fifth conductive sub-layer are copper, and the materials of the second conductive sub-layer, the third conductive sub-layer, the fourth conductive sub-layer and the sixth conductive sub-layer are molybdenum-nickel alloy.

16. The filter according to claim 1, wherein the filter further comprises:
a first seed layer, provided adjacent to a side, facing the base substrate, of the second conductive layer, and configured as a seed layer for generating the second conductive layer; and
a second seed layer, provided between the conductive pillar and a sidewall of the through-hole, and configured as a seed layer for generating the conductive pillar.

17. The filter according to claim 1, wherein the filter further comprises:
a fourth conductive layer, provided on a side, away from the first conductive layer, of the base substrate, and comprising a plurality of third conductive wires, the third conductive wire being connected between two conductive pillars.

18. The filter according to claim 17, wherein the plurality of conductive pillars comprises a plurality of first conductive pillars and a plurality of second conductive pillars, the plurality of first conductive pillars are spaced apart in a same direction as a direction in which the plurality of second conductive pillars are spaced apart, and the first conductive pillar and the second conductive pillar are provided in a row;
the third conductive wire is connected between the first conductive pillar and the second conductive pillar in a same row;
the first conductive wire is connected between the first conductive pillar and the second conductive pillar in adjacent rows, and each of the conductive pillars is connected to one of the first conductive wires.

19. The filter according to claim 17, wherein the filter further comprises:
a third seed layer, provided adjacent to a side, facing the base substrate, of the fourth conductive layer, and configured as a seed layer for generating the fourth conductive layer.

20. A method for manufacturing a filter comprising a first inductor, wherein the method comprises:
providing a base substrate;
forming, on the base substrate, a plurality of through-holes passing through the base substrate;
forming conductive pillars within the through-holes, the conductive pillars being configured to form a portion of a coil of the first inductor;
forming a first conductive layer on a side of the base substrate, the first conductive layer comprising a plurality of first conductive wires, the first conductive wire being connected between two of the conductive pillars, and the first conductive wires being configured to form a portion of the coil of the first inductor; and
forming a second conductive layer on a side, away from the base substrate, of the first conductive layer, the second conductive layer comprising second conductive wires, the second conductive wires corresponding to the first conductive wires respectively, and the second conductive wire being connected to the first conductive wire corresponding thereto through a via-hole.

21-33. (canceled)
